(19) United States
(12) Patent Application Publication
(10) Pub. No.: US 2026/0038566 A1
(43) Pub. Date: Feb. 5, 2026

(54) TEMPERATURE SENSOR READOUT FOR MEMORY SYSTEMS

(71) Applicant: Micron Technology, Inc., Boise, ID (US)

(72) Inventors: Graziano Mirichigni, Vimercate (IT); Marco Sforzin, Cernusco Sul Naviglio (IT)

(21) Appl. No.: 18/790,635

(22) Filed: Jul. 31, 2024

(51) Int. Cl. G11C 11/406

(52) U.S. Cl. CPC G11C 11/40626; G11C 11/40615

(57) ABSTRACT

Providing temperature sensor data to a memory controller is described herein. An example system includes a memory apparatus comprising a memory device, a controller coupled to the memory device and configured to receive a temperature status of the memory device from a first register coupled to the memory device, determine whether the temperature status is above a threshold value, retrieve a temperature alert associated with the memory device when the temperature status is above a threshold value from a second register coupled to the memory device, retrieve a temperature sensor value associated with the memory device stored in a third register coupled to the memory device in response to retrieving the temperature alert, and set a refresh interval of the memory device based on the temperature sensor value retrieved from the third register.

### TECHNICAL FIELD

The present disclosure relates generally to memory, and more particularly, to systems, apparatuses, and methods associated with temperature sensor data readout for memory.

### BACKGROUND

Memory devices are typically provided as internal, semiconductor, integrated circuits and/or external removable devices in computers or other electronic devices. There are many different types of memory including volatile and non-volatile memory. Volatile memory can require power to maintain its data and can include random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), and resistance variable memory such as phase change random access memory (PCRAM), resistive random access memory (RRAM), magnetic random access memory (MRAM), and programmable conductive memory, among others.

Memory devices can be utilized as volatile and non-volatile memory for a wide range of electronic applications in need of high memory densities, high reliability, and low power consumption. Non-volatile memory may be used in, for example, personal computers, portable memory sticks, solid state drives (SSDs), digital cameras, cellular telephones, portable music players such as MP3 players, and movie players, among other electronic devices.

Various computing systems can include processing resources that are coupled to memory (e.g., a memory system), which is associated with executing a set of instructions (e.g., a program, applications, etc.). A memory system can use a temperature sensor to control refresh operations of a memory device.

### BRIEF DESCRIPTION OF THE DRAWINGS

FIG. 1 illustrates a block diagram of a computing system including a memory system in accordance with a number of embodiments of the present disclosure.

FIG. 2 illustrates a schematic diagram of a data readout operation for a memory system in accordance with a number of embodiments of the present disclosure.

FIG. 3A illustrates a block diagram of a temperature status data frame format in accordance with a number of embodiments of the present disclosure.

FIG. 3B illustrates an example of data stored by temperature status registers of memory devices in accordance with a number of embodiments of the present disclosure.

FIG. 4A illustrates a block diagram of a temperature sensor data frame format in accordance with a number of embodiments of the present disclosure.

FIG. 4B illustrates an example of data stored by temperature sensor registers of memory devices in accordance with a number of embodiments of the present disclosure.

FIG. 5A illustrates a block diagram of a temperature sensor data frame format in accordance with a number of embodiments of the present disclosure.

FIG. 5B illustrates an example of data stored by temperature sensor registers of memory devices in accordance with a number of embodiments of the present disclosure.

### DETAILED DESCRIPTION

The present disclosure includes systems, apparatuses, and methods associated with temperature sensor data readout for memory. A number of embodiments include an apparatus comprising a memory device, a controller coupled to the memory device and configured to receive a temperature status of the memory device from a first register coupled to the memory device, determine whether the temperature status is above a threshold value, retrieve a temperature alert associated with the memory device when the temperature status is above a threshold value from a second register coupled to the memory device, retrieve a temperature sensor value associated with the memory device stored in a third register coupled to the memory device in response to retrieving the temperature alert, and set a refresh interval of the memory device based on the temperature sensor value retrieved from the third register.

Power consumption has been a performance bottleneck in computer and memory systems. As computer systems have advanced, energy demands have increased to accommodate these advancements which can affect the overall performance and latency of the memory system. Refresh operations are essential to the performance and longevity of memory systems, but in turn can require high energy demands. Efficient management of these refresh operations can lead to reduced power consumption and an overall increase in performance.

As performance requirements for memory increase, managing data retention has become increasingly important in view of the high power consumption associated with refresh operations on memory systems. Dynamic random access memory (e.g., DRAM) and other suitable memory systems store data as an electrical charge in memory cells. Over time, the chemical and physical properties of the memory cells change, causing the stored data to change. Refresh operations are required periodically in order to retain accurate data in memory systems. However, while refresh operations are being performed on the memory device, memory requests associated with the memory device become unavailable resulting in lowered system performance due to the time it takes to refresh data stored in the memory.

There are several refresh schemes that can be performed to restore the data integrity of memory devices, such as an All-Bank Refresh scheme or a Per-Bank Refresh scheme. Both refresh schemes employ different methods of refreshing memory cells at varying levels of memory and time intervals. An All-Bank Refresh scheme operates at an entire rank level such that refresh commands are initiated for some rows of all banks within the memory rank. A Per-Bank Refresh scheme operates bank-by-bank such that a refresh command is issued more frequently to refresh each bank within the memory device. Each refresh scheme has various down-time associated with normal memory access.

Temperature has a significant influence on the frequency at which refresh operations are performed on memory devices. As the temperature of a memory device increases, the chemical and physical properties of the memory cells change more rapidly causing the refresh rate to increase. Past approaches have utilized on-chip temperature sensors to monitor the changing temperature of the memory device during use and control the frequency at which refresh operations are performed. The legacy approach, however, provides a coarse temperature refresh interval and a longer system response time that makes its use for All-Bank Refresh and/or Per-Bank Refresh much less optimized.

In order to address these and other deficiencies of previous approaches, embodiments of the present disclosure can provide temperature sensor data associated with a memory device to a memory controller for controlling the performance of refresh operations of the memory device. The temperature sensor data can also be referred to as temperature data. In some examples, the temperature sensor data can provide a temperature status of the memory device, a temperature alert associated with a change in a temperature sensor value of the memory device, and/or an indication that a variation in the temperature sensor data is greater than a configurable temperature margin. The temperature sensor data can be used to adjust a refresh interval associated with the performance of refresh operations on a memory array of the memory device. The temperature sensor data can be provided to a memory controller to perform a precise adjustment of the refresh interval such that less power is used for refresh operations of the memory device. Additionally, a memory system in accordance with the present disclosure includes a fine regulation of a refresh interval of a memory array as compared with previous memory systems. For example, the memory system in accordance with the present disclosure can have decreased power consumption associated with the performance of refresh operations on the memory system compared to the performance of previous refresh operations on memory systems due to a more precise regulation of the refresh interval associated with refresh operations on the memory system.

The performance of a memory system can refer to the read or write latency and single bit addressability of the memory system. The performance of a memory system can be impacted by the high-energy demands of performing operations such as refresh operations on memory. The performance of memory systems in accordance with the present disclosure can be increased due to the reduced power consumption of performing an All-Bank Refresh and/or Per-Bank Refresh operation by providing a temperature sensor value to the memory controller for a fine regulation of the temperature refresh interval.

Tuning a refresh interval in accordance with the present disclosure can include providing a temperature sensor value to the memory controller for refresh power reduction. This approach can provide finer tuning of the refresh interval than previous approaches (e.g., MR4 function), which allows for a more precise adjustment of the refresh interval by directly providing the temperature sensor value to the memory controller.

As used herein, “a”, “an”, or “a number of” can refer to one or more of something, and “a plurality of” can refer to two or more such things. For example, a memory device can refer to one or more memory devices, and a plurality of memory devices can refer to two or more memory devices.

As used herein, an “apparatus” can refer to, but is not limited to, a variety of structures or combinations of structures, such as circuit or circuitry, a die or dice, a module, or modules, a device or devices, or a system of systems. For example, the memory system 108, the memory system controller 110, the memory components 116-N, may separately or collectively be referred to as an “apparatus.”

The figures herein follow a numbering convention in which the first digit or digits correspond to the drawing figure number and the remaining digits identify an element or component in the drawing. Analogous elements within a Figure may be referenced with a hyphen and extra numeral or letter. Such analogous elements may be generally referenced without the hyphen and extra numeral or letter. For example, elements 112-0₀, 112-1₀, . . . , 112-N₀ may collectively be referenced as 112. As used herein, the designators “N” and “X”, particularly with respect to reference numerals in the drawings, indicate that a number of the particular feature so designated can be included. As will be appreciated, elements shown in the various embodiments herein can be added, exchanged, and/or eliminated so as to provide a number of additional embodiments of the present disclosure. In addition, as will be appreciated, the proportion and relative scale of the elements provided in the figures are intended to illustrate certain embodiments of the present invention and should not be taken in a limiting sense.

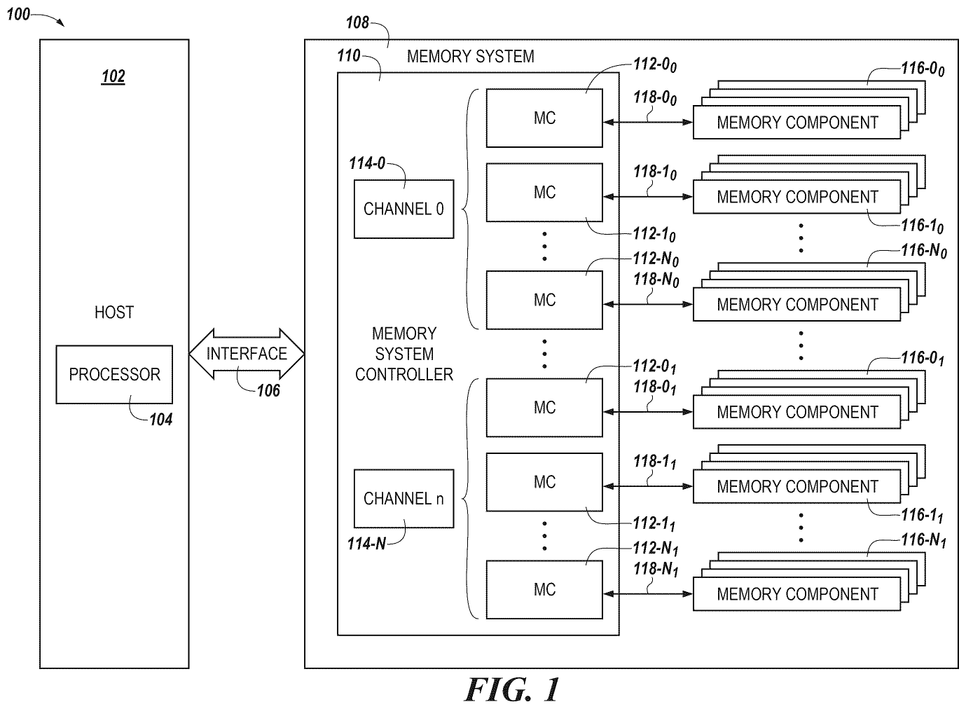

FIG. 1 is a block diagram of a computing system 100 including a memory system 108, a memory system controller 110, and a plurality of memory components 116-0₀, 116-1₀, 116-N₀, 116-0₁, 116-1₁, 116-N₁, collectively referred to as memory components 116, capable of implementing a number of embodiments of the present disclosure. The memory system controller 110 includes a plurality of memory channel controllers (e.g., MC) 112-0₀, 112-1₀, 112-N₀, 112-0₁, 112-1₁, 112-N₁, collectively referred to as memory channel controllers 112, for interfacing with memory components 116 corresponding to the respective memory channels 114-0, 114-N. The computing system 100 includes a host 102 and a processor 104. The computing system 100 can be a laptop computer, personal computer, digital camera, digital recording and playback device, mobile telephone, PDA, memory card reader, interface hub, sensor, Internet-of-Things (IoT) enabled device (e.g., thermostats, bulbs, locks, security systems, toothbrushes, pet feeders, etc.), among other systems, and the host 102 can include a number of processing resources 104 (e.g., one or more processors) capable of accessing the memory system 108 (e.g., via the memory system controller 110). The host 102 may be responsible for execution of an operating system (OS) and/or various applications that can be loaded thereto (e.g., from the memory system 108 via the memory system controller 110).

Although not shown in FIG. 1, the memory system controller can include a physical layer (PHY) for interfacing with the host 102 over interface 106, which can include a number of input/output (I/O) lines. The interface 106 can include various combinations of data, address, and control buses, which can be separate buses or one or more combined buses. In at least one embodiment, the interface 106 between the memory system controller 110 and the host 102 can be a peripheral component interconnect express (PCIe) physical and electrical interface operated according to a compute express link (CXL) protocol. In embodiments in which the interface 106 is operated under CXL protocol, the memory system controller 110 is configured to receive (e.g., from the host) memory access requests directed at the memory devices 116, and to provide (e.g., to the host) memory access responses corresponding to the memory access requests, according to CXL protocol. As non-limiting examples, the interface 106 can be a PCIe 5.0 interface operated in accordance with a CXL 2.0 specification or a PCIe 6.0 interface operated in accordance with a CXL 3.0 specification.

CXL is a high-speed central processing unit (CPU)-to-device and CPU-to-memory interconnect designed to accelerate next-generation data center performance. CXL technology maintains memory coherency between the CPU memory space and memory on attached devices such as accelerators, memory buffers, and smart I/O devices, which allows resource sharing for higher performance, reduced software stack complexity, and lower overall system cost. CXL is designed to be an industry open standard interface for high-speed communications, as accelerators are increasingly used to complement CPUs in support of emerging applications such as artificial intelligence and machine learning. CXL technology is built on the PCIe infrastructure, leveraging PCIe physical and electrical interfaces to provide advanced protocol in areas such as input/output (I/O) protocol, memory protocol (e.g., initially allowing a host to share memory with an accelerator), and coherency interface. CXL provides protocols with I/O semantics similar to PCIe (e.g., CXL.io), caching protocol semantics (e.g., CXL.cache), and memory access semantics (CXL.mem). CXL can support different CXL device types (e.g., Type 1, Type 2, and Type 3) supporting the various CXL protocols. Embodiments of the present disclosure are not limited to a particular CXL device type.

The memory system controller 110 may receive memory requests (e.g., in the form of read and/or write commands, which may be referred to as load and store commands, respectively) from the host 102. The memory system controller 110 can transfer commands and/or data between the host 102 and the memory system 108 over a number of interfaces, which can comprise physical interfaces such as buses, for example, employing a suitable protocol. Such a protocol may be custom or proprietary, or interfaces may employ a standardized protocol, such as Peripheral Component Interconnect Express (PCIe), Gen-Z, CCIX, or the like. The memory system controller 110 can comprise control circuitry, in the form of hardware, firmware, or software, or any combination of the three. As an example, the memory system controller 110 can comprise a state machine, a sequencer, and/or some other type of control circuitry, which may be implemented in the form of an application specific integrated circuit (ASIC) coupled to a printed circuit board. In a number of embodiments, the memory system controller 110 may be co-located with the host 102 (e.g., in a system-on-chip (SOC) configuration). Also, the memory system controller 110 may be co-located with the memory system 108.

The memory system 108 can comprise a number of physical memory “chips,” or dice which can each include a number of arrays (e.g., banks) of memory cells and corresponding support circuitry (e.g., address circuitry, I/O circuitry, control circuitry, read/write circuitry, etc.) associated with accessing the array(s) (e.g., to read data from the arrays and write data to the arrays). As an example, the memory system 108 can include a number of DRAM devices, SRAM devices, PCRAM devices, RRAM devices, FeRAM, phase-change memory, 3DXpoint, and/or Flash memory devices. In a number of embodiments, the memory system 108 can serve as main memory for the computing system 100.

The memory system controller 110 can be responsible for controlling various operations associated with executing memory access requests (e.g., read commands and write commands) from the host 102. For example, although not shown in FIG. 1, the memory system controller 110 can include a cache and various error circuitry (e.g., error detection and/or error correction circuitry) capable of generating error detection and/or error correction data for providing data reliability among other functionality in association with writing data to and/or reading data from the memory components 116, which can also be referred to as memory devices 116.

As described above, the memory system controller can include a number of memory channel controllers (e.g., media controllers) and a physical (PHY) layer that couples the memory system controller 110 to the memory devices 116. As used herein, the term “PHY layer” generally refers to the physical layer in the Open Systems Interconnection (OSI) model of a computing system. The PHY layer may be the first (e.g., lowest) layer of the OSI model and can be used to transfer data over a physical data transmission medium. In various embodiments, the physical data transmission medium includes memory channels 118-0₀, 118-1₀, 118-N₀, 118-0₁, 118-1₁, 118-N₁, collectively referred to as memory channels 118. The memory channels 118 can be, for example, 16-bit channels each coupled to 16-bit (e.g., ×16) devices, to two 8-bit (×8) devices; although embodiments are not limited to a particular interface. As another example, the channels 118 can each also include a two pin data mask inversion (DMI) bus, among other possible bus configurations. The memory system controller 110 can exchange data (e.g., user data and error detection and/or correction data) with the memory devices 116 via the physical pins corresponding to the respective memory channels 118. As described further herein, in a number of embodiments, the memory channels 118 can be organized as a number of channel groups, with the memory channels of each group being accessed together in association with executing various memory access operations and/or error detection and/or correction operations.

As shown in FIG. 1, the memory system controller 110 includes a plurality of memory channel controllers 112 for interfacing with memory components 116 corresponding to the respective memory channels 114. In this example, the memory channels 114 are organized as a number of channel groups 114-0 . . . , 114-N. Each channel group 114 comprises “N” memory channels 118. For instance, channel group 114-1 comprises memory channels 118-0₀, 118-1₀, . . . , 118-N₀, and channel group 114-N comprises memory channels 118-0₁, 118-1₁, . . . , 118-N₁. Although each channel group is shown as comprising the same quantity of memory channels 118, embodiments are not so limited.

In this example, the memory channel controllers 112-0₀, 112-1₀, . . . , 112-N₀ corresponding to channel group 114-1 are coupled to respective memory components 116-0₀, 116-1₀, . . . , 116-N₀ via respective memory channels 118-0₀, 118-1₀, . . . , 118-N₀. In another example, the memory channel controllers 112-0₀, 112-1₀, . . . , 112-N₀ can be implemented as a single memory channel controller driving “N” memory channels. Although not shown in FIG. 1, the memory system controller may include a PHY memory interface for coupling to the memory components 116. The channel groups 114-0 . . . 114-N can be operated independently by the memory system controller 110 such that memory access requests and/or error operations can be separately (and concurrently) performed on the memory components 116 corresponding to the respective channel groups 114.

In a number of embodiments, the memory components 116 may be DRAM memory devices, as described above. The memory components 116 may be arranged in ranks such that there are a number of memory components 116 coupled to a same memory channel controller 112. For example, a memory rank may consist of a group of DRAM chips that share the same chip select, or activation, signal. When the memory controller activates the chip select line, all the DRAM chips in that rank respond to the command simultaneously. Memory systems can be arranged in ranks of one, two, or more. In this example, memory components 116 are arranged in a rank of four, although embodiments are not so limited.

The memory devices 116 can include multiple memory arrays which can be grouped into one or more banks. The memory banks can each contain individual rows of memory cells that can store data associated with memory devices 116 or can have data written thereto.

Although not shown, data buses, including address buses and/or command buses can couple the memory components 116 to the memory system controller 110. The data buses can be configured to transfer data from the memory components 116 to the memory system controller 110 and/or to transfer data from the memory system controller 110 to the memory components 116. The command buses can be configured to provide commands from the controller 110 to the memory components 116. The commands can include, for example, read commands and/or write commands, among other possible commands that can be provided to the memory components 116. The address buses can include address information associated with the commands. For example, an address associated with a read command can be provided via address buses connected to memory devices 116 and memory system controller 110. The memory devices 116 can provide data responsive to receiving and/or processing the read command. Temperature data associated with memory devices 116 may be provided to the memory system controller 110 along with the data requested as part of performing the read operation. The temperature data can be provided to the memory system controller 110 at a same time that the data is provided to the memory system controller 110, but embodiments are not so limited.

The temperature data can be associated with the data retrieved from memory devices 116. Both the temperature data and the data can be provided to the controller 110 responsive to receiving a command from the controller 110. A latency (e.g., deterministic read latency) between receiving a command from the controller 110 and providing the data and/or the temperature data can be the same for both the data and the temperature data. As such, a first bit of the temperature data and a first bit of the data and a last bit of the temperature data and the data can be provided to the controller 110 at the same time. For example, the temperature data can be provided to the controller 110 concurrently with data retrieved from memory devices 116.

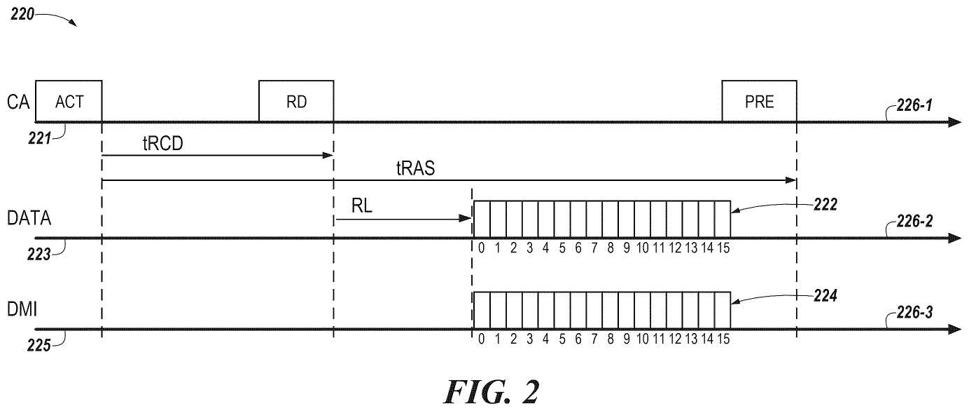

In other examples, the temperature data and the data read from any one of the memory devices 116 can be provided to the controller 110 at different times (e.g., without being sent at the same time). In such examples, a first bit of the temperature data is sent at a different time as a first bit of the data read from the memory device. The temperature data, that is associated with a first read command used to generate a first data set, can be provided before the memory devices 116 fulfills a second read command. The temperature data is described in more detail with reference to FIGS. 2-5.

FIG. 2 illustrates a schematic diagram of a data readout operation for a memory system in accordance with a number of embodiments of the present disclosure. The data access operation illustrated in FIG. 2 can be performed in the computing system 100 described in accordance with FIG. 1, for example.

The schematic diagram 220 of the data access operation illustrated in FIG. 2 can be performed to access data stored in a memory device, such as memory devices 116 of FIG. 1. Data stored in any one of the memory devices 116 can be accessible by the memory system controller 110. A process of accessing data stored in a memory device by the controller can be referred to herein as an access operation, and/or data access operation. An access operation, such as a read or write operation, can be communicated (e.g., sent by a host such as the host 102) to a memory device as a series of commands (e.g., a command sequence). The commands can be communicated to a memory device by the controller over command/address bus 221. The commands can be received by a memory device and can trigger corresponding operations at the memory device to read, write, or otherwise access data stored by the memory device (e.g., at one or more memory cells of the memory device). The data stored in or written to the memory device can be communicated between the memory controller and the memory device over data bus 223.

Various operations are included in the performance of a data access operation. An activation operation, an access operation, and a precharge operation can be performed to access a row of memory cells of a memory bank of a memory device. The activation operation, access operation, and precharge operations can be initiated by respective activation, access, and precharge commands. These commands can be received by the memory device from the memory system controller via a command/address bus (e.g., CA bus 221). CA bus 221, data bus 223, and the direct media interface 225 (e.g., DMI) can be components of the one or more channels 118. In some examples, the activation operation can be performed before an access operation to open rows 226-2, 226-3. Additionally, the precharge operation can be performed to close the activated rows 226-2, 226-3. In some cases, a precharge operation can be performed before a subsequent access operation of a row of the same memory bank. The corresponding commands can be communicated from the memory controller to the memory device as a series of commands (e.g., a command sequence). The commands can include an activation command, a data access command, and a precharge command, and can be received in the order the corresponding operations are performed.

Data access operations (e.g., row access operations) can have an associated latency and timing signal. For example, the latency of a row access operation performed by the memory device can be associated with the internal timing of a data access operation, which can be associated with a set of timing signals generated by a phase generator. Although not illustrated, each of the memory devices can include internal control circuitry (e.g., a state machine and/or other control logic) configured to control a phase generator associated with a memory bank of the memory device. In some examples, the set of timing signals can include tRCD (e.g., the minimum time required between an activation command and a data access command), which can be longer due to increased latency associated with the activation command or data access operation. The precharge operation can be associated with a row-active time (tRAS) timing signal. The tRAS can be the amount of time (e.g., clock signals, a minimum quantity of clock cycles) between the memory device receiving the activation command and the memory device receiving the precharge command.

To initiate a row access operation, the memory device can receive the activation command, which can be sent from the memory controller. The activation command can be associated with opening a row of a memory array (e.g., a memory array of any one of memory devices). The activation operation can be executed over the tRCD. In some cases, the memory controller can start a timer corresponding to the tRCD to determine when to send subsequent commands associated with the row access operation.

While the rows 226-2, 226-3 are open, the memory device can receive the data access command. For example, the data access command can be a read command, a write command, or another type of data access command. The data access command can include an instruction to access the row opened in association with the activation operation. Execution of the data access command can occur after the tRCD.

After completing the first data access operation, the memory device can receive a precharge command. The precharge command can trigger a precharge phase, which can include timing or other signals for internal operations to close the row (e.g., the precharge operation).

Data can be accessed from memory cells of a memory device via data bus 223. Each row of a memory array comprises memory cells which store a number of bits. When a respective row is activated, a data access operation can be performed as described above in which data is transferred via the data bus. As illustrated in FIG. 2, bits numbered 1-15 are located on the row line 226-2 (e.g., RL). The number of bits included in FIG. 2 is purely exemplary, and more or less bits may be included on the row line. When a data access operation is performed, data is accessed from any of bits 222 and transferred via the data bus 223.

As described further herein, various embodiments can include use of registers (e.g., on a memory device) to provide temperature data associated with a memory device for tuning of a refresh interval (e.g., tREFI) involved in the performance of refresh operations on the memory device. The registers may be mode registers. A register may indicate a temperature alert notifying the memory controller that there has been a change in the temperature data stored in the register since the last read operation was performed. A register may indicate that there has been a variation in temperature data greater than a configurable temperature margin. The temperature data stored in such registers may be used by the memory controller 110 to tune the refresh interval.

Data stored in such registers may be provided to the memory controller for every data access operation performed on memory devices. The mode register of interest may be referred to as the Master Error Log which may include Master Errors Status bits for indicating a temperature alert. The Master Error Log may include data associated with temperature sensor data of the memory devices. The Master Error Log may be a formerly unused mode register (e.g., MR125), but embodiments are not so limited. A temperature alert may be provided to the memory controller during every read operation performed on the memory devices via the data mask interface signal (e.g., DMI signal). The Master Error Log may include a plurality of status bits indicating errors associated with the memory system. The Master Error Status may be repeated on a plurality of bits within status bits 224. For example, the Master Error Status is MR125 OP[0] repeated on beat 4, 5, and 6 of the status bits 224. Embodiments are not so limited to a particular number of bits.

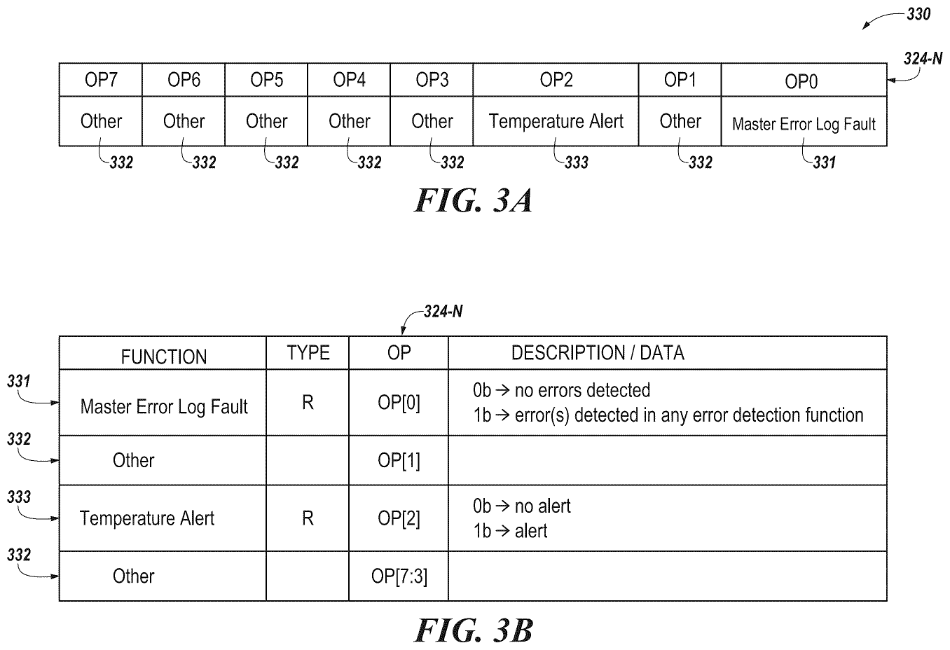

FIG. 3A illustrates a block diagram of a temperature status data frame format in accordance with a number of embodiments of the present disclosure. FIG. 3A includes a mode register data frame 330. The mode register data frame 330 can be used to provide temperature status data as described in FIG. 2. The mode register may be referred to as MR125 for purposes of explanation, but embodiments are not limited to a particular mode register. For example, MR125 may be referred to as Master Error Log, and more specifically, OP[0] of MR125 may be referred to as Master Error Log Fault.

The mode register data frame 330 includes operation bits (e.g., OP) 324-N, collectively referred to as 324, where “N” corresponds to the operation bit number. For example, operation bit 324-0 corresponds to OP[0] and operation bit 324-1 corresponds to OP[1]. In this example, eight operation bits are shown but embodiments are not so limited. Each operation bit 324 corresponds to a particular operating parameter stored in the mode register in association with the memory system. As illustrated in FIG. 3A, operand 324-0 indicates data stored in the Master Error Log Fault and operand 324-2 indicates a temperature alert. The remaining operation bits may be programmed to correspond to other data and may be reserved for future use.

FIG. 3B illustrates an example of data stored by temperature status registers of memory devices in accordance with a number of embodiments of the present disclosure. The example data illustrated in FIG. 3B may correspond to the mode register described with reference to FIG. 3A.

In the example of FIG. 3B, the function of operand 324-0 is to indicate whether an error has been detected. Operand 324-0 may correspond to data stored in the Master Error Log. Operand 324-0 may have read only permissions, as illustrated by “R” in the “type” column. A binary value of “0” for operand 324-0 indicates that no errors have been detected. Alternatively, a binary value of “1” for operand 324-0 indicates that an error has been detected in any error detection function.

The Master Error Log Fault (e.g., OP[0]) informs the memory controller that there has been a change on the mode register since the last read operation was performed. If OP[0] is set to “1”, the memory controller may check OP[2] to see if there is a temperature alert notification. If there is a temperature alert notification, the memory controller may read the temperature sensor value stored in a separate mode register (e.g., MRxz). The memory controller can use the temperature sensor value stored in MRxz to determine a fine regulation of refresh interval tREFI.

Operands 324-1, 324-3, 324-4, 324-5, 324-6, 324-7 may be reserved to provide other functionality in association with the memory system and is not programmed in relation to the temperate status of the memory devices in this example.

The function of operand 324-2 is to indicate whether a temperature alert has occurred. The mode register associated with operand 324-2 may have read-only permissions. A binary value of “0” for operand 324-2 indicates that no alert has been detected. Alternatively, a binary value of “1” for operand 324-2 indicates that a temperature alert has been detected. When OP[2] is set to “1”, the memory controller may read the temperature sensor value stored in a separate register. A temperature alert may indicate that there has been a temperature sensor value variation greater than a configurable temperature margin. The temperature sensor value may be provided by an analog-to-digital converter (e.g., ADC) temperature sensor embedded within the memory device. An ADC temperature sensor may be provided for each respective memory device, or there may be a single ADC temperature sensor provided for use in monitoring the temperature of the memory system as a whole. Embodiments are not limited to a particular number of ADC temperature sensors.

The temperature alert is notified through the Master Error Status on the DMI signal in every read operation. Upon receiving the temperature alert notification, the memory controller reads the temperature sensor value stored in a separate mode register. The temperature sensor readout value may be stored in a mode register XZ (e.g., MRxz). Mode register XZ represents a new mode register that was not implemented in memory devices in previous approaches. The memory controller may use the temperature sensor value stored in MRxz to tune the refresh interval. Tuning the refresh interval according to the temperature sensor values stored in MRxz may reduce the power consumption associated with the performance of refresh operations on the memory system. The temperature alert notification and Master Error Status bits may be reset after reading the temperature sensor readout value.

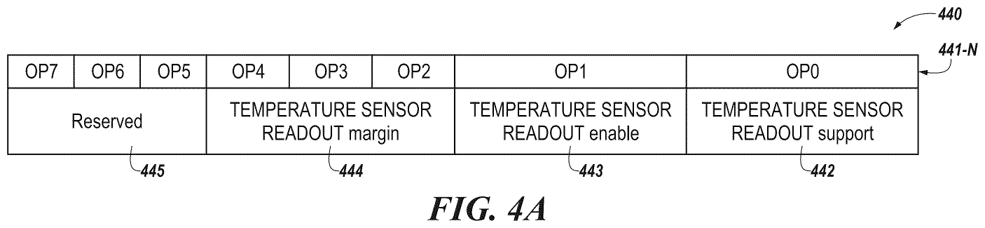

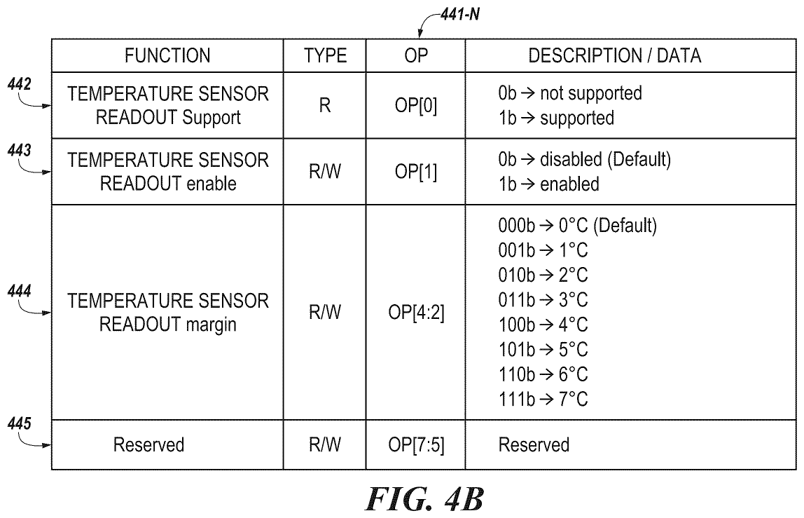

FIG. 4A illustrates a block diagram of a temperature sensor data frame format in accordance with a number of embodiments of the present disclosure. FIG. 4A includes a mode register data frame 440. The mode register data frame 440 can be used to provide temperature status data as described in FIGS. 2, 3A, and 3B. The mode register may be referred to as MRxy.

The mode register data frame 440 includes operation bits (e.g., OP) 441-N, collectively referred to as 441, where “N” corresponds to the operation bit number. For example, operation bit 441-0 corresponds to OP[0] and operation bit 441-1 corresponds to OP[1]. In this example, eight operation bits are shown but embodiments are not so limited. Each of the operation bits 441 corresponds to a particular operating parameter stored in the mode registers of the memory system.

The mode register, as illustrated in FIG. 4A, stores operands 0-7 (e.g., OP[0], OP[1], . . . , OP[7]). In the example of FIG. 4A, the function of operand 441-0 is to provide temperature sensor readout support, the function of operand 441-1 is to provide temperature sensor readout enable, and operands 441-2, 441-3, 441-4 provide a temperature sensor readout margin. Operands 441-5, 441-6, 441-7 may be reserved for future programming.

FIG. 4B illustrates an example of data stored by temperature sensor registers of memory devices in accordance with a number of embodiments of the present disclosure. The data illustrated in FIG. 4B may correspond to the mode register data frame illustrated in FIG. 4A.

As illustrated in FIG. 4B, the mode register that stores the operand 441-0 may have read only permissions. A binary value of “0” for operand 441-0 indicates that a temperature sensor readout operation is not supported. Alternatively, a binary value of “1” for operand 441-0 indicates that a temperature sensor readout operation is supported.

In the example of FIG. 4B, the function of operand 441-1 is to enable a temperature sensor readout operation. A mode register that stores the operand 441-1 can have read-write permissions. A binary value of “0” for operand 441-1 indicates that a temperature sensor readout operation is not enabled. This is the default set value for operand 441-1. Alternatively, a binary value of “1” for operand 441-1 indicates that a temperature sensor readout operation is enabled.

In FIG. 4B, operands 441-2, 441-3, 441-4 are represented by bits 2-4 (e.g., OP[4:2]). In this example, the function of OP[4:2] is to provide a temperature sensor readout margin. The mode register that stores operands 441-2, 441-3, 441-4 can have read-write permissions. For operands 441-2, 441-3, 441-4, a binary value of “000” indicates a temperature margin of 0° C. This is the default setting for the temperature sensor readout margin operands. A binary value of “001” indicates a temperature margin of 1° C. Also, a binary value of “010” corresponds to a temperature margin of 2° C. There are different binary values corresponding to varying temperature margins. The binary values illustrated in FIG. 4B are not to be taken in a limiting sense. Other configurations are possible.

As described with reference to FIGS. 2 and 3, when a temperature alert is provided to the memory controller, this indicates that there has been a temperature sensor value variation greater than a configurable temperature margin, which may correspond to mode register MRxy.

As illustrated in FIG. 4B, operands 441-5, 441-6, 441-7 (e.g., OP[7:5]) may be reserved for alternative programming to provide various functionality. The mode register that stores OP[7:5] can have read-write permissions.

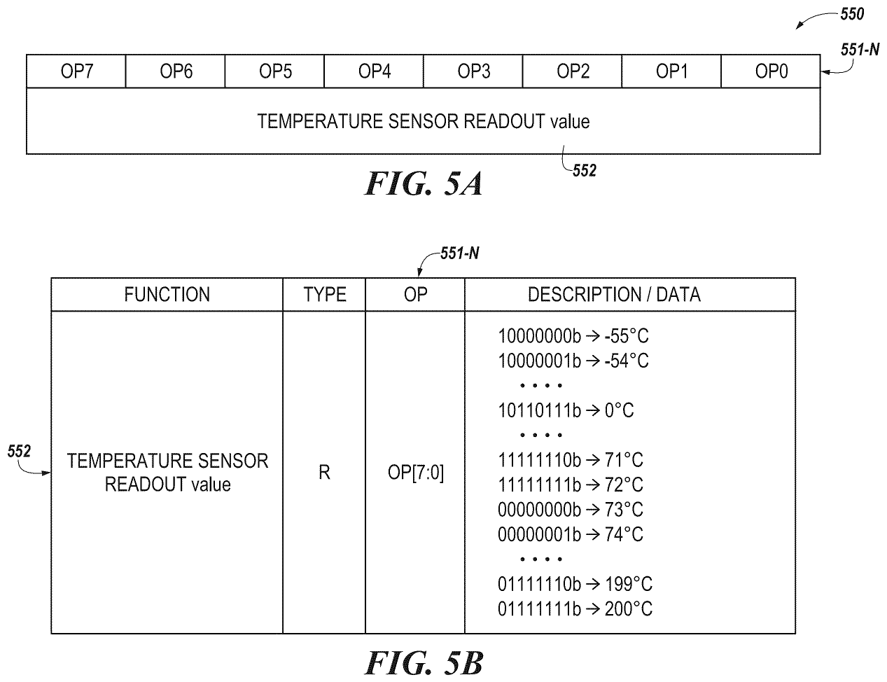

FIG. 5A illustrates a block diagram of a temperature sensor data frame format in accordance with a number of embodiments of the present disclosure. FIG. 5A includes a mode register data frame 550. The mode register data frame 550 can be used to provide temperature status data as described in FIGS. 2 and 3. The mode register may be referred to as MRxz.

The mode register data frame 550 includes operation bits (e.g., OP) 551-N, collectively referred to as 551, where “N” corresponds to the operation bit number. For example, operation bit 551-0 corresponds to OP[0] and operation bit 551-1 corresponds to OP[1]. In this example, eight operation bits are shown but embodiments are not so limited. Each operation bit 551 corresponds to a particular operating parameter stored in the mode register in association with the memory system. In the example of FIG. 5A, the function of operands 551 is to provide temperature sensor readout values.

FIG. 5B illustrates an example of data stored by temperature sensor registers of memory devices in accordance with a number of embodiments of the present disclosure. The data illustrated in FIG. 5B may correspond to the mode register data frame illustrated in FIG. 5A.

As illustrated in FIG. 5B, the mode register that stores operands 551-N may have read only permissions. A binary value of “10000000” indicates a temperature sensor value of −55° C. A binary value of “01111111” indicates a temperature sensor readout value of 200° C. The binary values illustrated in FIG. 5B are not to be taken in a limiting sense. Other configurations are possible.

As illustrated in FIG. 5B, mode register MRxy provides temperature sensor values in 1° C. increments, which allows for a more precise tuning of tREFI. By providing the memory controller with less variation in the temperature sensor values recorded for the memory system, a more sensitive adjustment of tREFI is possible which in turn, allows for decreased energy demands on the computing system as a whole. Providing the temperature sensor value to the memory controller allows for a fine regulation of tREFI to reduce power consumption for All-Banks Refresh and/or Per-Bank Refresh operation schemes.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combination of the above embodiments, and other embodiments not specifically described herein will be apparent to those of ordinary skill in the art upon reviewing the above description. The scope of a number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
a memory device;
a controller coupled to the memory device and configured to:
receive a temperature status of the memory device from a first register coupled to the memory device;
determine whether the temperature status is above a threshold value;
retrieve a temperature alert associated with the memory device when the temperature status is above a threshold value from a second register coupled to the memory device;
retrieve a temperature sensor value associated with the memory device stored in a third register coupled to the memory device in response to retrieving the temperature alert; and
set a refresh interval of the memory device based on the temperature sensor value retrieved from the third register.

2. The apparatus of claim 1, wherein the temperature status is provided to the controller in every read operation performed on the memory device.

3. The apparatus of claim 1, wherein determining whether the temperature status is above the threshold value includes determining whether an error has been detected in the first mode register.

4. The apparatus of claim 3, wherein the controller sets the refresh interval of the memory device when the temperature status is above the threshold value.

5. The apparatus of claim 3, wherein determining whether the temperature status is above the threshold value includes determining whether at least one bit among a plurality of bits of the first register is set.

6. The apparatus of claim 5, wherein the setting of the at least one bit among the plurality of bits is associated with an indication of a change in a temperature of the memory device.

7. The apparatus of claim 6, wherein the change in the temperature of the memory device is indicative of at least a 1° C. increment in the temperature of the memory device.

8. A memory device, comprising:
a memory array;
a controller coupled to the memory array and configured to:
receive a request for data stored in the memory array;
retrieve the data from the memory array responsive to receiving the request;
receive a temperature status of the memory device from a first register coupled to the memory device in response to receiving the request for data;
determine whether the temperature status is above a threshold value;
retrieve a temperature alert associated with the memory device when the temperature status is above a threshold value from a second register coupled to the memory device;
retrieve a temperature sensor value associated with the memory device stored in a third register coupled to the memory device in response to retrieving the temperature alert; and
set a refresh interval of the memory device based on the temperature sensor value retrieved from the third register.

9. The memory device of claim 8, wherein the temperature status of the memory device corresponds to a first plurality of bits of the memory array.

10. The memory device of claim 9, wherein the first plurality of bits is associated with an indication of a change in a temperature of the memory device.

11. The memory device of claim 8, wherein the temperature sensor value of the memory device is sensed by an analog-to-digital temperature sensor coupled to the memory device.

12. The memory device of claim 8, wherein the temperature sensor value is stored in the third register in 1° C. increments.

13. The memory device of claim 12, wherein the controller is further configured to determine a fine regulation of the refresh interval of the memory device based on the temperature sensor value stored in the third register.

14. A method comprising:
receiving, from a controller coupled to a memory device, a request for data;
receiving a temperature status of the memory device from a first register coupled to the memory device in response to receiving the request for data;
determining whether the temperature status is above a threshold value;
retrieving a temperature alert associated with the memory device when the temperature status is above a threshold value from a second register coupled to the memory device;
retrieving a temperature sensor value associated with the memory device stored in a third register coupled to the memory device in response to retrieving the temperature alert; and
setting a refresh interval of the memory device based on the temperature sensor value retrieved from the third register.

15. The method of claim 14, further comprising:
resetting a plurality of bits of the first register associated with the temperature status of the memory device in response to adjusting the refresh interval of the memory device; and
resetting a plurality of bits of the second register associated with the temperature alert of the memory device in response to adjusting the refresh interval of the memory device.

16. The method of claim 14, wherein resetting the plurality of bits of the first register and resetting the plurality of bits of the second register is done responsive to retrieving the temperature sensor value from the third register.

17. The method of claim 14, wherein setting the refresh interval of the memory device includes increasing or decreasing the amount of time between the performance of a refresh operation of the memory device.

18. The method of claim 14, wherein determining whether the temperature status is above the threshold value includes determining whether at least one bit among a plurality of bits of the first register is set.

19. The method of claim 17, wherein the setting of at least one bit among the plurality of bits of the first register indicates a change in the temperature value of the memory device that is greater than a set margin.

20. The method of claim 14, wherein the first register, the second register, and the third register are separate registers coupled to the memory device.
